(19) United States
(12) Patent Application Publication
(10) Pub. No.: US 2006/0120424 A1
(43) Pub. Date: Jun. 8, 2006

(54) Semiconductor laser device

(75) Inventor: Akira Tanaka, Kanagawa-ken (JP)

Correspondence Address: BANNER & WITCOFF, LTD., ATTORNEYS FOR RESERVE;ATTORNEYS FOR CLIENT NO. 000449, 001701, 1001 G STREET, N.W., 11TH FLOOR, WASHINGTON, DC, 20001-4597, US

(73) Assignee: Kabushiki Kaisha Toshiba, Minato-ku (JP)

(21) Appl. No.: 11/285,376

(22) Filed: Nov. 23, 2005

(30) Foreign Application Priority Data
Nov. 25, 2004 (JP) 2004-339824

(51) Int. Cl. H01S 5/00

(52) U.S. Cl. 372/43.01

(57) ABSTRACT

In one or more aspects, a semiconductor laser device is described that may include a first cladding layer of a first conductivity type; an active layer provided on the first cladding layer; a second cladding layer of a second conductivity type provided on the active layer, the second cladding layer having a ridge waveguide provided between a first edge and a second edge; a dielectric layer provided on the ridge waveguide, the dielectric layer being lower in refractive index than the second cladding layer; at least a first region in which the dielectric layer is provided on the ridge waveguide; and a second region in which the dielectric layer is not provided on the ridge waveguide; wherein the first region is extended along a cavity length direction from one of the first edge and the second edge, the second region is adjacent to the first region and the second region is extended from the other one of the first edge and the second edge.

### CROSS REFERENCE TO RELATED APPLICATION

This application is based upon and claims the benefit of priority from Japanese Patent Application No. 2004-339824, filed on Nov. 25, 2004, the entire contents of which are incorporated herein by reference.

### BACKGROUND OF THE INVENTION

Research and development for next generation DVDs are proceeding. The next generation DVD is a high density optical disc, which is capable of storing much data such as long hour recording of high resolution TV. Such DVDs are read or written by a laser having 400 nm emission wavelength.

This wavelength is shorter than a wavelength of a laser for the present DVDs, which emits a 650 nm laser. The 650 nm laser is made of InAlGaP based semiconductor. A GaN based semiconductor or other material based semiconductors is suitable for obtaining a shorter emission wavelength.

One example of a conventional semiconductor laser is GaN-based ridge waveguide semiconductor laser device. In the semiconductor laser device, a double hetero junction made of InGaAlN-based semiconductor is grown on a GaN substrate. A part of an upper part cladding layer (p-type cladding layer) is a stripe shape.

### SUMMARY OF THE INVENTION

In some aspects of the present invention, a semiconductor laser device may include a first cladding layer of a first conductivity type; an active layer provided on the first cladding layer; a second cladding layer of a second conductivity type provided on the active layer, the second cladding layer having a ridge waveguide provided between a first edge and a second edge; a dielectric layer provided on the ridge waveguide, the dielectric layer being lower in refractive index than the second cladding layer; a first region in which the dielectric layer is provided on the ridge waveguide; and a second region in which the dielectric layer is not provided on the ridge waveguide; wherein the first region is extended along a cavity length direction from one of the first edge and the second edge, the second region is adjacent to the first region and the second region is extended from the other one of the first edge and the second edge.

In other aspects of the invention, a semiconductor laser device may include a first cladding layer of a first conductivity type; an active layer provided on the first cladding layer; a second cladding layer of a second conductivity type provided on the active layer, the second cladding layer having a ridge waveguide provided between a first edge and a second edge; a dielectric layer provided on the ridge waveguide, the dielectric layer being lower in refractive index than the second cladding layer; a first region in which the dielectric layer is provided on the ridge waveguide; a second region in which the dielectric layer is not provided on the ridge waveguide; and a metal electrode provided on the ridge waveguide of the first region and the second region; wherein the first region is extended from one of the first edge and the second edge along a cavity length direction and the second region is adjacent to the first region.

### BRIEF DESCRIPTIONS OF THE DRAWINGS

FIG. 1 is a schematic front view of a semiconductor laser device in accordance with a first embodiment of the present invention.

FIG. 2 is a schematic side view of the semiconductor laser device as shown in FIG. 1.

FIG. 3 is a schematic sectional view along a cavity direction of the semiconductor laser device as shown in FIG. 1.

FIG. 4 is a schematic cross sectional view showing a manufacturing process of the semiconductor laser device in accordance with the first embodiment.

FIG. 5 is a schematic cross sectional view showing a manufacturing process of the semiconductor laser device in accordance with the first embodiment.

FIG. 6 is a schematic cross sectional view showing a manufacturing process of the semiconductor laser device in accordance with the first embodiment.

FIG. 7 is a schematic cross sectional view showing a manufacturing process of the semiconductor laser device in accordance with the first embodiment.

FIG. 8 is schematic view of a semiconductor laser device showing a far field pattern (FFP) of the laser beam.

FIG. 9 is a graph showing FFP of a vertical direction of the semiconductor laser device in accordance with the first embodiment.

FIG. 10 is a graph showing FFP of a horizontal direction of the semiconductor laser device in accordance with the first embodiment.

FIG. 11 is a schematic perspective view of a semiconductor laser device in accordance with an example different from the first embodiment.

FIG. 12 is a cross sectional view of the semiconductor laser device as shown in FIG. 11.

FIG. 13 is a graph showing FFP of a vertical direction of the semiconductor laser device as shown in FIG. 12 and FIG. 13.

FIG. 14 is a graph showing FFP of a horizontal direction of the semiconductor laser device as shown in FIG. 12 and FIG. 13.

FIG. 15 is a schematic cross sectional view of a semiconductor laser device in accordance with a second embodiment of the present invention.

### DETAILED DESCRIPTION OF THE INVENTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as follows.

### A First Embodiment

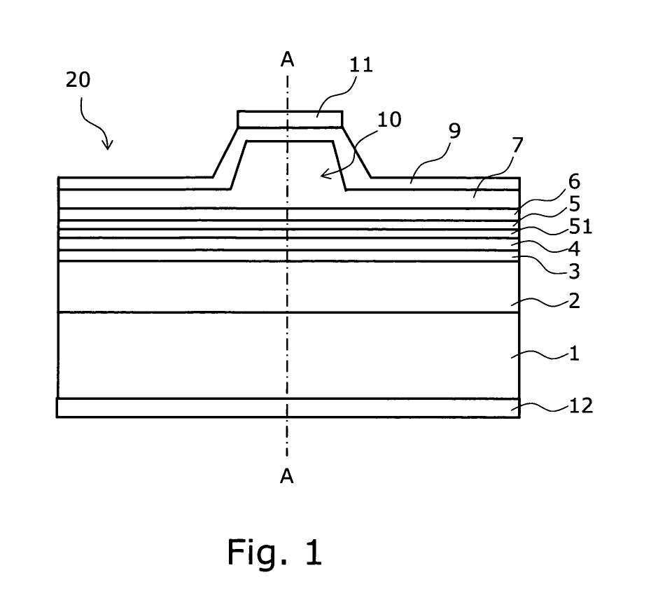

A first embodiment of the present invention will be explained with reference to FIG. 1 to FIG. 10.

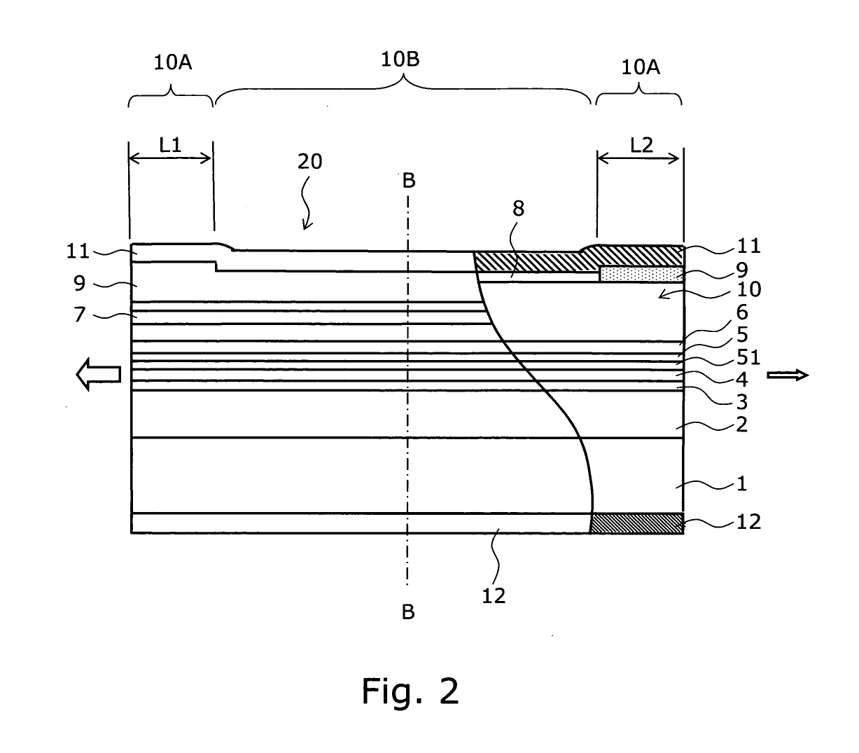

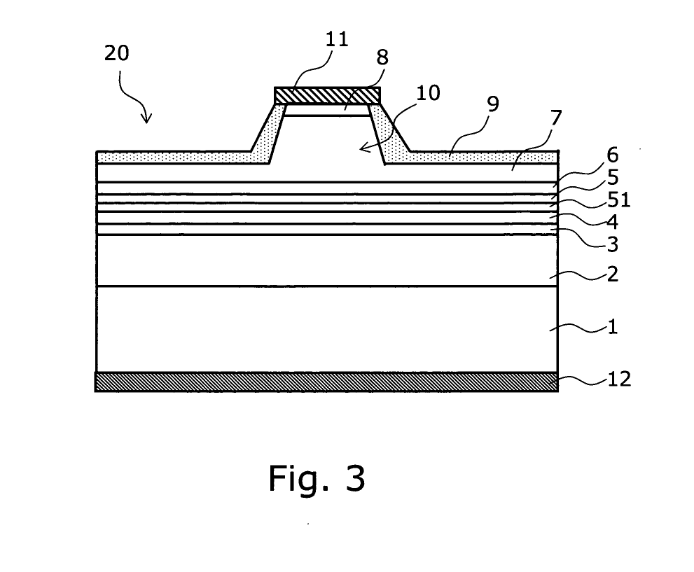

FIG. 1 is a schematic front view of a semiconductor laser device in accordance with a first embodiment of the present invention. FIG. 2 is a schematic side view of the semiconductor laser device as shown in FIG. 1. FIG. 3 is a schematic sectional view along a cavity direction of the semiconductor laser device as shown in FIG. 1.

A structure of a semiconductor laser device in accordance with this embodiment is explained hereinafter.

As shown in FIG. 1, in a semiconductor laser device 20 (or laser chip 20 hereinafter), an n type A10.08Ga0.92N cladding layer 2 (the thickness: 0.2-1.0 micrometers), an n type GaN optical guide layer 3 (the thickness: 0.01-0.10 micrometers), an MQW (multi quantum well) active layer 4, an AlGaN diffusion blocking layer 51, a p+ type Al_{0.08}Ga_{0.82}N overflow blocking layer 5, a p type GaN optical guide layer 6 (the thickness: 0.01-0.10 micrometers), a p type A10.08Ga0.92N cladding layer 7 (the thickness: 0.5-1.0 micrometers) and a p+ type GaN contact layer (the thickness: 0.02-0.2 micrometers) are provided on an n type GaN substrate 1 in this order. It is appreciated that other thicknesses may be used to adjust for size, light output, and material constraints.

The active layer 4 is made of In0.15Ga_{0.85}N/In_{0.02}Ga_{0.80}N. A thickness of an In_{0.15}Ga_{0.85}N well layer of the active layer is 2-5 nanometers, and a thickness of an In_{0.20}Ga_{0.80}N barrier layer of the active layer is 3-10 nanometers. For example, the number of the well may be 2-4.

A stripe shaped ridge waveguide 10 is provided in the p type AlGaN cladding layer 7.

The semiconductor laser 20 is configured to emit laser from the active layer 4 in a direction, which is perpendicular to a page face of FIG. 1. Besides, the emission surface and the opposite face are cleaved faces. An anti-reflection film or a high-reflection film may be coated on the cleaved faces, respectively.

In this embodiment, a cross sectional structure, which is perpendicular to cavity length direction of the semiconductor laser device, is different between a front or rear face (illustrated in FIG. 1) and a central region (illustrated in FIG. 3). Namely, as shown in FIG. 3, a p side electrode 11 is contact with a dielectric layer 9 near the front or rear face of the laser chip. However as shown in FIG. 2, the p side electrode 11 is contact with a p+ GaN contact layer 8 near the central region of the laser chip.

The dielectric layer 9 covers the both sides of the ridge waveguide 10 in the central region and near the front and the rear face of the chip. Near the front and the rear face of the chip, the dielectric layer 9 is selectively provided on the top of the ridge waveguide 10. In other words, as shown in FIG. 2, the semiconductor laser device 20 has a forming region 10A in which the dielectric layer 9 is provided on top of the ridge waveguide 10 and a non-forming region 10B in which the dielectric layer 9 is not provided on top of the ridge waveguide 10. The forming region 10A is extended distance L1 from the front face and distance L2 the rear face along the cavity length direction. The non-forming region 10B is provided between the front face and the rear face of the forming region 10A. The non-forming region 10B is adjacent to the forming region 10A. The FFP (far field pattern) in which the partial noise of the laser is reduced is obtained.

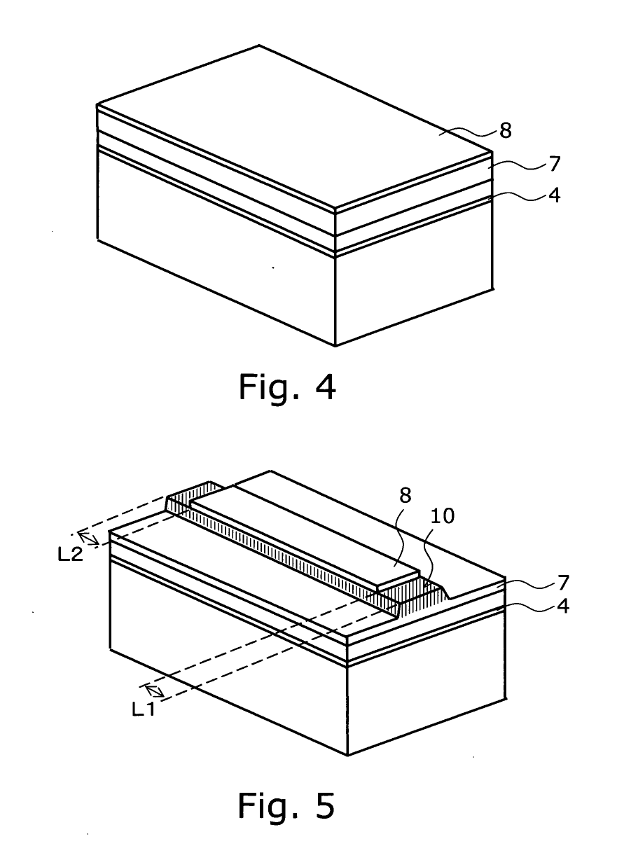

The manufacturing process of the semiconductor 20 will be explained hereinafter with reference to FIGS. 4-7.

As shown in FIG. 4, a laminate layer (the n type cladding layer 2, the n type guide layer 3, the active layer 4, the diffusion blocking layer 51, the overflow block layer 5, the p type guide layer 6, the p type cladding layer 7 and the p+ type contact layer 8) is grown on the substrate 1. In FIG. 4, the layers except for the active layer 4, the p type cladding layer 7 and the p+ type contact layer 8 are omitted for making it clear.

As shown in FIG. 5, the ridge waveguide 10 can be provided by etching the p+ contact layer 8 and a part of the p type cladding layer 7. Alternatively, the ridge may be created through other approaches (including but not limited to depositing the ridge). A stripe shaped p type contact layer 8 is obtained. The front face and the rear face of the p+ type GaN layer 8 is removed L1 and L2 respectively. The length L1 and L2 may be the same length or different length. Thus the stripe shaped ridge waveguide 10 having a trapezoid shape is obtained as shown the hatching in FIG. 5. It is preferable that the ridge stripe is made by high accuracy pattering such as dry etching, as the transverse mode of the laser is controlled by the ridge waveguide 10. Alternate shapes are possible including but not limited to shapes having stepped sides, parallel sides, and/or triangular cross sections.

As shown in FIG. 6, the dielectric layer 9 is formed on the exposed GaN contact layer 8. For example, an AlN layer having 0.2-0.7 micrometers in its thickness may be formed. The dielectric layer 9 is formed to cover the both sides of the stripe shaped ridge waveguide 10. Light is confined in the ridge waveguide 10 with the difference of the refraction index. The region where the dielectric layer 9 is provided on the top surface of the ridge waveguide 10 is corresponding to the forming region 10A shown in FIG. 2 and the region where the dielectric layer 9 is not provided on the ridge waveguide 10 is corresponding to the non-forming region 10B shown in FIG. 2.

The laser is emitted from a part of the active layer, corresponding to the width W of the ridge waveguide 10. Controllability of the transverse mode is improved and a wide range optical output beam in which reduced kink is obtained.

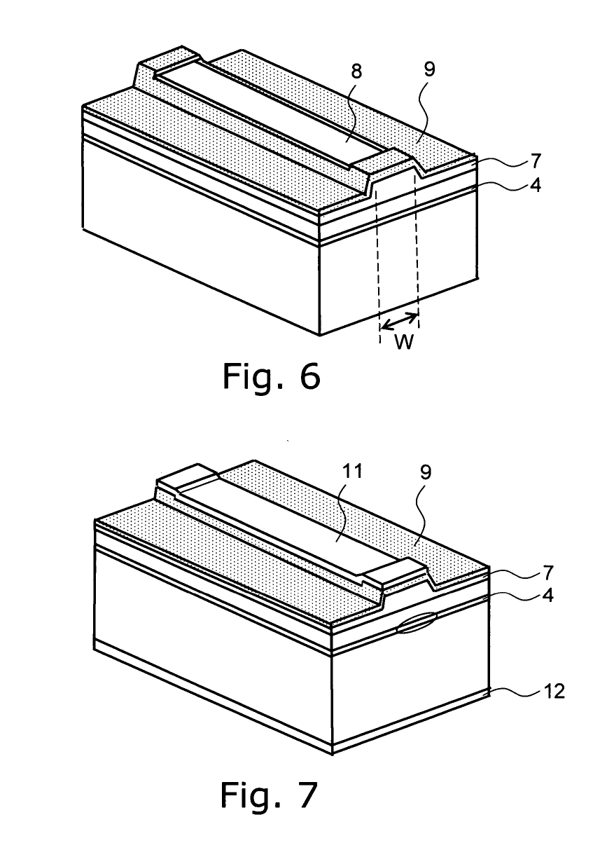

As shown in FIG. 7, the p side electrode 11 is formed on the exposed p+ type GaN contact layer 8 and the top surface of the ridge waveguide 10 (near the front face and the rear face). Alternatively, the p side electrode 11 may be not formed on the non forming region 10B. However, in the aspect of manufacturing, it is preferable that the metal electrode (the p side electrode 11) is provided both of the forming region 10A and non forming region 10B.

The n side electrode 12 is formed on the back face of the substrate 1. The n side electrode may be single layer (Ti, Pt Au, and Al), multilayer or alloy.

In the semiconductor laser element of this embodiment, the p side electrode 11 may be in contact with the dielectric layer 9 near the front and rear end, and in the central region of the cavity the p side electrode 11 may be in contact with the p+ contact layer 8.

The p+ type AlGaN overflow block layer 5 may be doped with p type impurities such as Mg in high concentration. An overflow of electron current from the n type GaN substrate 1 is prevented.

The layers from the n type cladding layer 2 to the active layer 4 are grown in relatively low temperature (e.g. less than 1000 centigrade). However, the overflow block layer 5, the p type guide layer 6 and the p type cladding layer 7 can be grown in a higher temperature environment. An AlGAN diffusion block layer 51 may be provided to prevent the doped Mg from diffusing to the active layer 4.

An super lattice layer, which can be laminated with 1-5 nanometers AlGaN and GaN in alternating layers, may be provided instead of n type AlGaN cladding layer 2 and p type AlGaN cladding layer 7. The stress due to lattice mismatching (such as block cracking) is reduced and operation voltage is reduced. For example, a 1 micrometer cladding layer is created by laminating the 2.5 nanometers GaN and the 2.5 nanometers AlGaN alternatively for approximately 200 times. Mg may be doped in the GaN layer.

AlN (refractive index: about 2.2), Ta₂O₅ (refractive index: about 2.3), TiO2 (refractive index: about 2.3), SiN (refractive index: about 1.9-2.1), Al₂O₃ (refractive index: about 1.7) and SiO₂ (refractive index: about 1.5) may be adapted as the dielectric layer 9. The refractive index as shown here is representative value in 400 nm.

The characteristic of the semiconductor laser device in accordance with this first embodiment will be explained hereinafter.

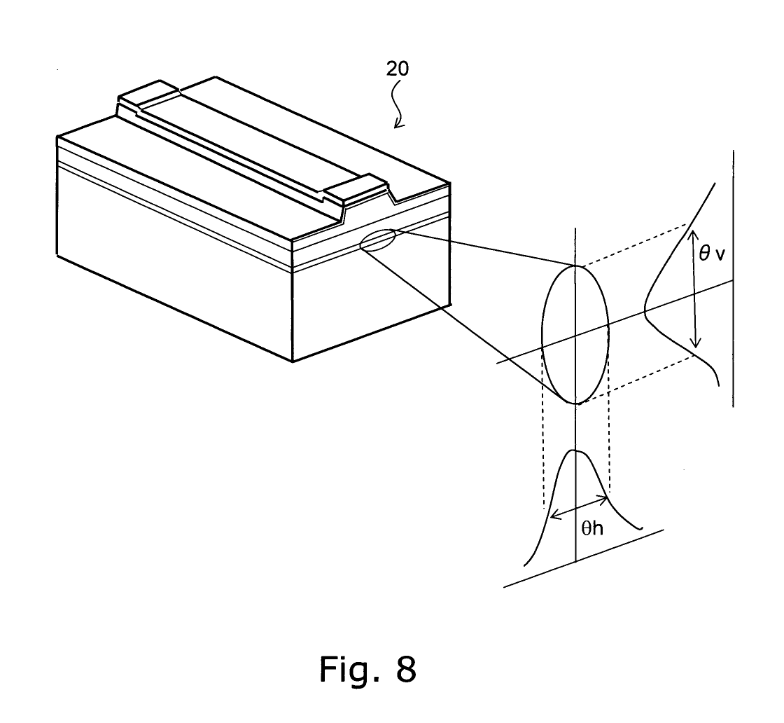

FIG. 8 is schematic view of a semiconductor laser device showing FFP (far field pattern) of laser beam.

The beam emitted from the semiconductor laser device 20 is spread as being far from the chip (the semiconductor laser device). Generally, an angle of the beam divergence vertical to the pn junction face is greater than an angle of the beam divergence horizontal to the pn junction face.

FWHM θv (full width at half maximum) along the vertical direction is defined as an angle which is the 50% of the peak value of the relative emission intensity distribution along the vertical axis.

FWHM θh (full width at half maximum) along the horizontal direction is defined as an angle which is the 50% of the peak value of the relative emission intensity distribution along the horizontal axis.

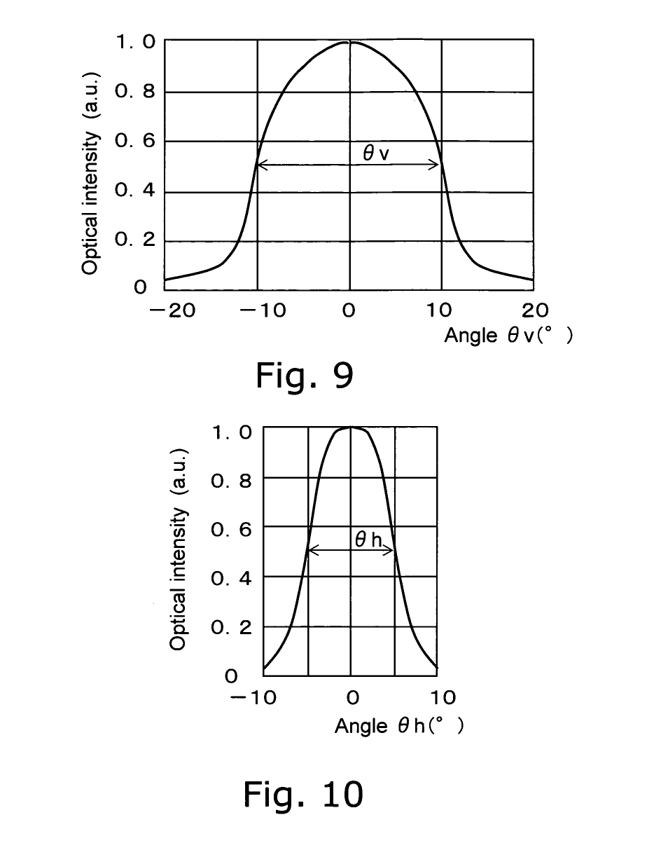

FIG. 9 is a graph showing FFP of a vertical direction of the semiconductor laser device in accordance with the first embodiment. FIG. 10 is a graph showing FFP of a horizontal direction of the semiconductor laser device in accordance with the first embodiment.

The FFP of the semiconductor laser device in accordance with this embodiment has a few noises along the vertical axis and the horizontal axis. θv is about 20 degree and Oh is about 10 degree. These values meet the optical requirement of the 400 nm laser the next generation DVDs.

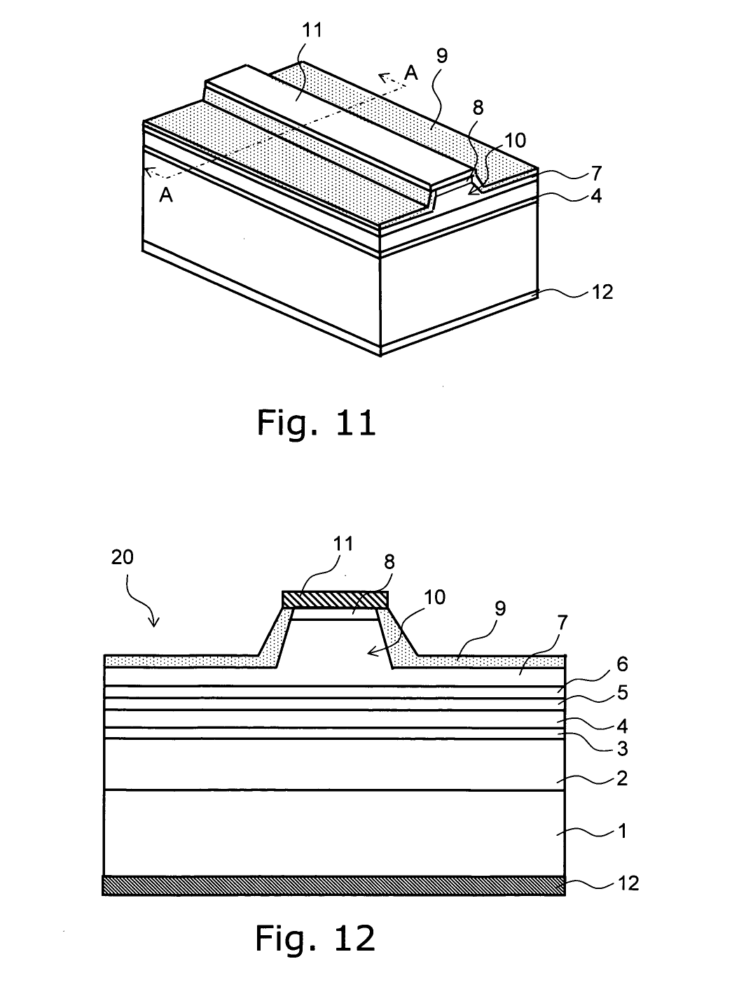

The FFP which is a representative characteristic of semiconductor laser will be explained with reference to a comparative example. The comparative example will be explained with reference to FIGS. 11-14.

FIG. 11 is a schematic perspective view of a semiconductor laser device of the comparative example. FIG. 12 is a cross sectional view of the semiconductor laser device as shown in FIG. 11. With respect to each portion of this comparative example, the same portions of the semiconductor laser device of the first embodiment shown in FIG. 1 to FIG. 10 are designated by the same reference numerals, and its explanation of such portions is omitted.

In this comparative example, a ridge waveguide 10 made of a p type AlGaN has substantially the same cross sectional structure along a direction which is perpendicular to a page face of FIG. 12. Namely, in a cross sectional view which is cut along a parallel line to A-A the p type GaN contact layer 8 is contact with the p type AlGaN cladding layer 7. Generally it is hard to grow p type Al_{0.08}Ga_{0.92}N cladding layer 7 having equaled to or more than 1 micrometer thickness without crystal defects on the p type GaN guide layer 6, as the lattice constant of AlGaN and GaN is different. On the other hand, the p+ type GaN contact layer 8 has a greater refractive index than the p type Al_{0.08}Ga_{0.92}N cladding layer 7. Thus the wave guide mode is spread to the p+ GaN contact layer 8 from the Al_{0.08}Ga_{0.92}N cladding layer 7 which is not enough thickness to confine the light.

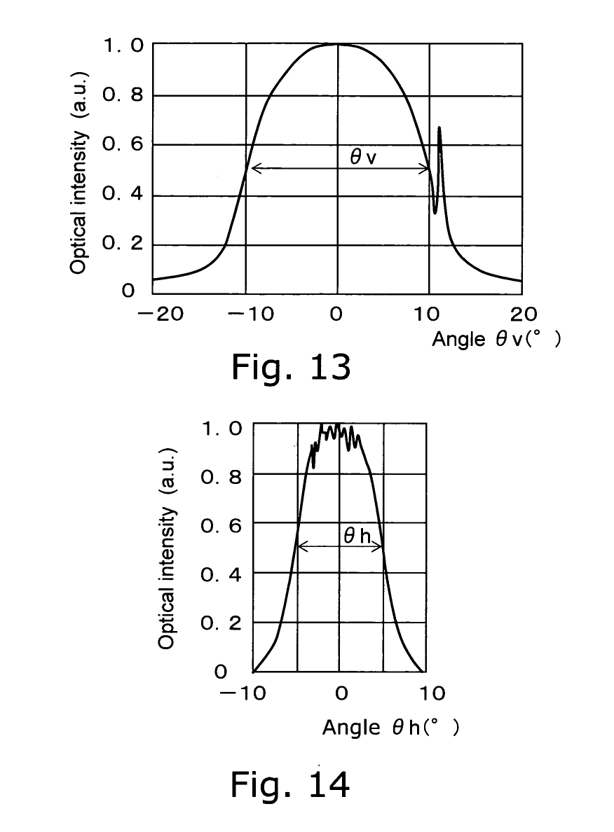

FIG. 13 is a graph showing FFP of a vertical direction of the semiconductor laser device as shown in FIG. 12 and FIG. 13. FIG. 14 is a graph showing FFP of a horizontal direction of the semiconductor laser device as shown in FIG. 12 and FIG. 13.

As shown in FIG. 13, the FFP has noise near 10 degree of θv. As shown in FIG. 14, the FFP also has noise in the horizontal direction θh. These noises may cause an error in detecting a focusing error, a tracking error, other errors or a signal when the semiconductor laser device of the comparative example is used as an optical pick up device. Moreover when the semiconductor laser device of the comparative example having unregulated noise is used as an optical pick up device of the rewritable type, it is hard for the laser beam emitted from the semiconductor laser device of the comparative example to control accurately the temperature of the recording layer of the optical disc.

As comparing to this comparative example, the FFP of the semiconductor laser device of the first embodiment as shown in FIGS. 1-10 is relatively small. One reason is that the dielectric layer 9 (e.g. the thickness 0.2-0.7 micrometers) is provided on the p type AlGaN layer 7. It is hard to grow p type Al_{0.08}Ga_{0.92}N cladding layer 7 having equaled to or more than 1 micrometer thickness without crystal defects on the p type GaN guide layer 6, as the lattice constant of AlGaN and GaN is different. The thickness is not enough thickness to confine in the active layer 4. On the other hand, in the semiconductor laser device of this first embodiment the dielectric layer 9 is provided on the ridge waveguide 10 near the front and rear faces. So light is able to be confined.

It is preferable that the lengths L1 and L2 front and rear faces are 5-50 micrometers respectively. If the length is no more than 5 micrometers, the noise of the FFP is not controllable and the output laser has disorder. If the length is less than 50 micrometers, the contact area between the contact layer 8 and the ridge waveguide 10 is small and the threshold voltage (operation voltage) of the semiconductor laser device may be increased. In case that the refractive index of the layer provided on the ridge waveguide 10 near the front and rear face is smaller than that of the p type AlGaN cladding layer 7 (refractive index: about 2.5), the light is confined. Thus the noise of the FFP is reduced.

However if the refractive index of the layer provided on the ridge waveguide 10 near the front and rear face is too small, the confinement by the dielectric layer 9 is too large and the FFP along the vertical direction is not asymmetry. If the asymmetry of the FFP is greater, the laser beam passed thorough a lens may be asymmetry and the power control is difficult during rewriting or overwriting.

The dielectric layer 9 may be SiN (refractive index: about 1.9-2.1), Al₂O₃ (refractive index: about 1.7) or SiO₂ (refractive index: about 1.5). It is preferable for improving the symmetry of the FFP that the refractive index of the dielectric layer 9 is no less than 2.0 such as AlN (refractive index: about 2.2), Ta₂O₅ (refractive index: about 2.3) or TiO₂ (refractive index: about 2.3).

### A Second Embodiment

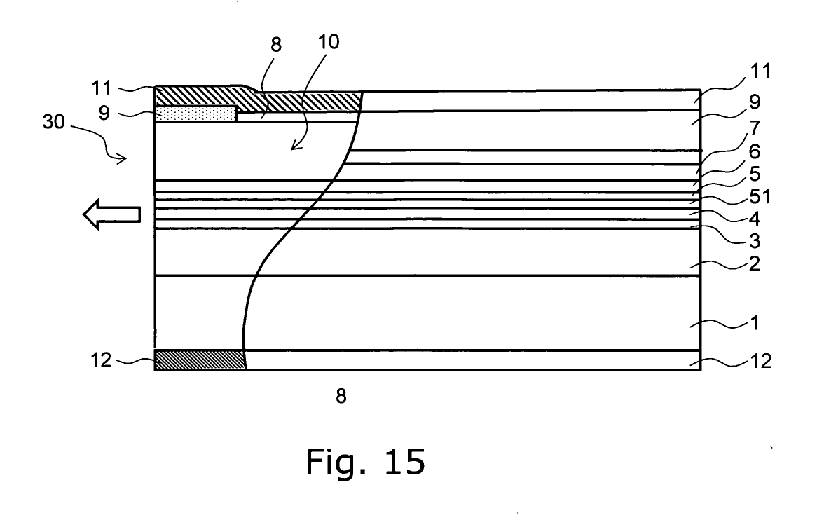

FIG. 15 is a schematic cross sectional view of a semiconductor laser device in accordance with a second embodiment of the present invention. With respect to each portion of this comparative example, the same portions of the semiconductor laser device of the first embodiment shown in FIG. 1 to FIG. 10 are designated by the same reference numerals, and its explanation of such portions is omitted.

In this embodiment, the dielectric layer 9 is provided on the ridge waveguide 10 near the front face 30. The dielectric layer 9 is not provided on the ridge waveguide 10 near the rear face. The laser emitted from the rear face is used as monitoring for the laser output but not irradiated to an optical disc. In other words, the noise of the FFP of the laser from the rear face is not so important for practical use. Since the contact area between the contact layer 8 and the ridge waveguide 10 is larger, the threshold voltage (operation voltage) is capable of being reduced.

As above mentioned, the semiconductor laser device of the first and the second embodiments has a dielectric layer which covers the top surface of the p type cladding layer near the front and/or rear face. The dielectric layer has lower refractive index than that of the p type cladding layer. Even if the light is spread from the p type cladding layer near the front of rear face, the light is confined by the dielectric having low refractive index. The FFP is improved.

An optical disc drive device for next generation DVD may be obtained by collecting the laser having little noise with a lens.

The embodiments mentioned above are explained a structure which is grown on the GaN substrate. However the semiconductor laser device is not limited to the GaN substrate. Other semiconductor laser devices are available, such as a structure grown on a sapphire substrate by ELOG (epitaxial lateral over growth).

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

For example, the semiconductor laser device is not limited to InAlGaN structure. Other semiconductor laser devices are available, such as InGaAlP, GaN, GaAlP and InP by using a III-V compound semiconductor, II-VI compound semiconductor, and so on.

Other embodiment of the present invention may be possible by changing the shape, size, material, and positional relations of the ridge waveguide type semiconductor laser device in design by one skilled in the art.

What is claimed is:

1. A semiconductor laser device, comprising:
a first cladding layer of a first conductivity type;
an active layer provided on the first cladding layer;
a second cladding layer of a second conductivity type provided on the active layer, the second cladding layer having a ridge waveguide provided between a first edge and a second edge;
a dielectric layer provided on the ridge waveguide, the dielectric layer being lower in refractive index than the second cladding layer;
a first region in which the dielectric layer is provided on the ridge waveguide; and
a second region in which the dielectric layer is not provided on the ridge waveguide;
wherein the first region is extended along a cavity length direction from one of the first edge and the second edge, the second region is adjacent to the first region and the second region is extended from the other one of the first edge and the second edge.

2. A semiconductor laser device of claim 1, further comprising:
a contact layer provided on the ridge waveguide in the second region; and
a metal electrode provided on the contact layer in the second region.

3. A semiconductor laser device of claim 1, wherein the active layer is made of InxAlyGa1−x−yN(0≦x≦1, 0≦y≦1, x+y≦1).

4. A semiconductor laser device of claim 1, wherein the second cladding layer is made of InxAlyGa1−x−yN(0≦x≦1, 0≦y≦1, x+y≦1).

5. A semiconductor laser device of claim 1, wherein the first region is extended from an emission surface along a cavity length direction.

6. A semiconductor laser device of claim 2, wherein the contact layer is narrower in the band gap than the second cladding layer.

7. A semiconductor laser device of claim 1, wherein a length of the first region along the cavity length is no less than 5.0 micrometers and no more than 50 micrometers.

8. A semiconductor laser device of claim 5, wherein a length of the first region along the cavity length is no less than 5.0 micrometers and no more than 50 micrometers.

9. A semiconductor laser device of claim 1, wherein the dielectric layer is made of one of AlN, Ta₂O₅, TiO₂, Si₃N₄, Al₂O₃ and SiO₂.

10. A semiconductor laser device of claim 2, wherein the dielectric layer in the second region is thicker than the contact layer in the first region.

11. A semiconductor laser device, comprising:
a first cladding layer of a first conductivity type;
an active layer provided on the first cladding layer;
a second cladding layer of a second conductivity type provided on the active layer, the second cladding layer having a ridge waveguide provided between a first edge and a second edge;
a dielectric layer provided on the ridge waveguide, the dielectric layer being lower in refractive index than the second cladding layer;
a first region in which the dielectric layer is provided on the ridge waveguide;
a second region in which the dielectric layer is not provided on the ridge waveguide; and
a metal electrode provided on the ridge waveguide of the first region and the second region;
wherein the first region is extended from one of the first edge and the second edge along a cavity length direction and the second region is adjacent to the first region.

12. A semiconductor laser device of claim 11, wherein the second region is extended from the other one of the first edge and the second edge.

13. A semiconductor laser device of claim 11, further comprising a contact layer provided between the metal electrode and the ridge waveguide in the second region.

14. A semiconductor laser device of claim 11, wherein the first region is extended along a cavity length direction from an emission surface.

15. A semiconductor laser device of claim 12, wherein the first region is extended along a cavity length direction from an emission surface.

16. A semiconductor laser device of claim 13, wherein the contact layer is narrower in the band gap than the second cladding layer.

17. A semiconductor laser device of claim 11, wherein a length of the first region along the cavity length is no less than 5.0 micrometers and no more than 50 micrometers.

18. A semiconductor laser device of claim 15, wherein a length of the first region along the cavity length is no less than 5.0 micrometers and no more than 50 micrometers.

19. A semiconductor laser device of claim 11, wherein the dielectric layer is made of one of AlN, Ta₂O₅, TiO₂, Si₃N₄, Al₂O₃ and SiO₂.

20. A semiconductor laser device of claim 11, wherein the dielectric layer in the second region is thicker than the contact layer in the first region.
